(19) United States
(12) Patent Application Publication
(10) Pub. No.: US 2025/0029863 A1
(43) Pub. Date: Jan. 23, 2025

(54) ELECTROSTATIC CHUCK MODULE

(71) Applicant: SAMSUNG ELECTRONICS CO., LTD., Suwon-si (KR)

(72) Inventor: Naoyuki TAKADA, Yokohama-shi (JP)

(21) Appl. No.: 18/625,030

(22) Filed: Apr. 2, 2024

(30) Foreign Application Priority Data
Jul. 18, 2023 (JP) 2023-116985

(51) Int. Cl. H01L 21/683; H05B 3/28

(52) U.S. Cl. CPC H01L 21/6833; H05B 3/283; H05B 2203/005

(57) ABSTRACT

An electrostatic chuck module operates at temperatures above the heat resistance temperature of a resin. The electrostatic chuck module includes: a base that includes a flow path for a coolant disposed below the base, a concave part disposed on the base, and a convex part disposed along an outer circumference of the base; an insulator disposed in the concave part of the base; a resistance heating element disposed on or within the insulator; a crack plate disposed on the insulator and the resistance heating element; and a ceramics plate disposed on the crack plate and that includes an electrode that adsorbs a target object with static electricity. The convex part of the base is bonded to the crack plate.

### CROSS-REFERENCE TO RELATED APPLICATION

This application claims priority under 35 U.S.C. 119 from Japanese Patent Application No. 2023-116985, filed on Jul. 18, 2023 in the Japanese Intellectual Property Office, the contents of which are herein incorporated by reference in their entirety.

### TECHNICAL FIELD

Embodiments of the present disclosure are directed to an electrostatic chuck module.

### DISCUSSION OF THE RELATED ART

An electrostatic chuck module operating at high temperature has been developed. The electrostatic chuck includes a metal base that has a base surface and a base back surface, a main substrate that is disposed on the base surface of the metal base and is formed of ceramics, and an adsorption electrode that is provided on the main substrate, and further includes a heater provided on the main substrate, and an adhesive layer disposed between the metal base and the main substrate. The main substrate includes an insulation layer disposed closer to the metal base than to the heater.

The insulation layer is equipped with multiple micro spaces arranged at intervals of a predetermined distance from one another on the same plane.

The electrostatic chuck operates at a temperature of 150° C. or higher. However, since the adhesive layer uses silicone resin for fixing high-temperature components, the electrostatic chuck cannot withstand temperatures above the resin's heat resistance.

### SUMMARY

Embodiments of the present disclosure provide an electrostatic chuck module that operates at temperatures above the heat resistance temperature of a resin while being equipped with a base for cooling.

According to an embodiment of the present disclosure, an electrostatic chuck module includes: a base that includes a flow path for a coolant disposed below the base, a concave part disposed on the base, and a convex part disposed along an outer circumference of the base; an insulator disposed in the concave part of the base; a resistance heating element disposed on or within the insulator; a crack plate disposed on the insulator and the resistance heating element; and a ceramics plate disposed on the crack plate and that includes an electrode that adsorbs a target object with static electricity. The convex part of the base is bonded to the crack plate.

The resistance heating element may include a plurality of resistance heating elements, the plurality of resistance heating elements are arranged in a concentric circular manner, and the plurality of resistance heating elements are independently heated to a temperature of 300° C. or higher.

A difference between thermal expansion coefficients of the ceramics plate and the crack plate may be ±2×10−6/K or less at operating temperatures.

A width of the convex part may be between 2 mm and 5 mm.

The electrostatic chuck module may further include an inorganic adhesive that directly or indirectly bonds the crack plate to the insulator via.

The electrostatic chuck module may further include insulating material interposed between the crack plate and the insulator, where the resistance heating element may not be in direct contact with the crack plate.

A labyrinth structure may be disposed below the convex part of the base.

The electrostatic chuck module may further include dish springs or members with spring force that fix the crack plate to the base.

According to another embodiment of the present disclosure, an electrostatic chuck module includes: a base that includes a flow path for a coolant disposed below the base, a concave part disposed on the base, and a convex part disposed along an outer circumference of the base; an insulator disposed in the concave part of the base; a resistance heating element disposed on or within the insulator; and a crack plate disposed on the resistance heating element and in contact with the convex part. A width of the convex part is between 2 mm and 5 mm.

According to another embodiment of the present disclosure, an electrostatic chuck module includes: a base that includes a flow path for a coolant disposed below the base, a concave part disposed on the base, and a convex part disposed along an outer circumference of the groove; an insulator disposed in the concave part of the base; a resistance heating element disposed on or within the insulator; an inorganic adhesive disposed on the resistance heating element; and a crack plate disposed on the inorganic adhesive. The inorganic adhesive fixes the crack plate to the insulator and the resistance heating element, and the crack plate is in contact with the convex part and spaced apart from the concave part.

According to the aforementioned and other embodiments of the present disclosure, an electrostatic chuck module that operates at temperatures above the heat resistance temperature of a resin can be provided. The electrostatic chuck module is usable at temperatures of 450° C. or higher.

### BRIEF DESCRIPTION OF THE DRAWINGS

FIG. 1 is a schematic view of an electrostatic chuck module according to an embodiment.

FIG. 2 is an enlarged schematic view of an electrostatic chuck module according to an embodiment.

FIG. 3 is an enlarged schematic view of another electrostatic chuck module according to an embodiment,

FIG. 4 is a graph of a relationship between a thermal expansion coefficient of the materials for an electrostatic chuck module according to an embodiment.

FIG. 5 is a graph of as relationship between a difference in thermal expansion coefficients between the materials for an electrostatic chuck module according to an embodiment and the stress occurring between these materials.

FIG. 6 illustrates a configuration of the thickness of a convex part of an electrostatic chuck module according to an embodiment.

FIG. 7 is a graph of simulation results of a relationship between the thickness of the convex part of the electrostatic chuck module according to an embodiment, the temperature deviation in a crack plate of the electrostatic chuck module according to an embodiment, and surface deformation.

FIG. 8 illustrates an electrostatic chuck module according to an embodiment, fixed with fastening members.

FIG. 9 is a graph of surface deformations of an electrostatic chuck module according to an embodiment when not fixed with fastening members and when fixed with fastening member.

### DETAILED DESCRIPTION

Embodiments of the present disclosure will hereinafter be described with reference to the accompanying drawings, but embodiments of the present disclosure are not necessarily limited thereto. Furthermore, not all components described in the following embodiments are essential as means for solving objectives of embodiments. For clarity of explanation, omissions and simplifications may be appropriately made in the following descriptions and drawings. In the drawings, the same elements may be assigned the same reference numerals, and repetitive explanations may be omitted.

### Configuration of an Electrostatic Chuck Module

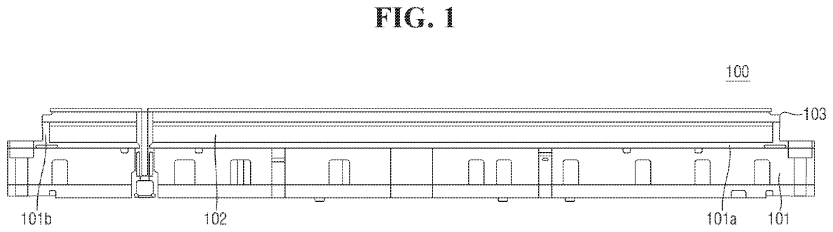

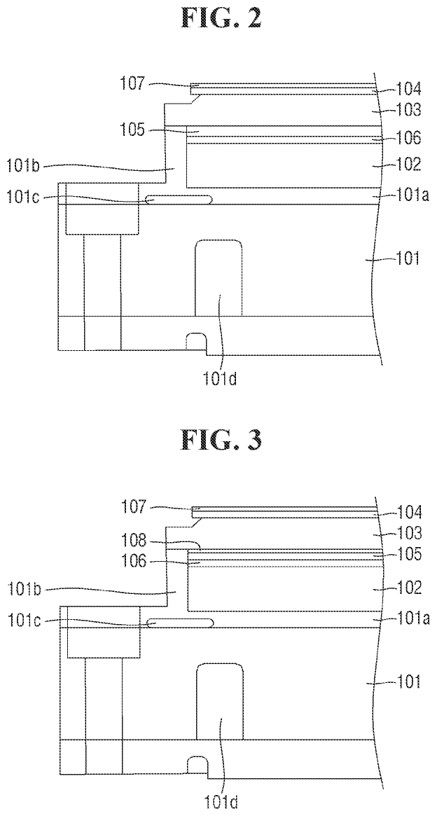

FIG. 1 is a schematic view of an electrostatic chuck module according to an embodiment. FIG. 2 is an enlarged schematic view of an electrostatic chuck module according to an embodiment of the present disclosure. FIG. 3 is an enlarged schematic view of another electrostatic chuck module according to an embodiment of the present disclosure.

A configuration of an electrostatic chuck 100 module according to an embodiment of the present disclosure will hereinafter be described with reference to FIG. 1. The electrostatic chuck module 100 is, for example, a module that uses static electricity to hold a wafer substrate during an etching process in the manufacture of a semiconductor dynamic random-access memory (DRAM).

Referring to FIGS. 1 through 3, in an embodiment, the electrostatic chuck module 100 includes a base 101, an insulator 102, a resistance heating element 106, a crack plate 103, and a ceramics plate 104. In some embodiments, the electrostatic chuck module 100 further includes an insulating material 108.

The base 101 is a stand with cooling capabilities. The base 101 cools a hot crack plate and thereby prevents the heat of the hot crack plate from diffusing to a lower part of the electrostatic chuck module 100. The base 101 includes a flow path 101d for a coolant disposed below the base, a convex part 101b disposed along an outer circumference of the base, and a concave part 101a disposed on the base. In addition, the base 101 includes a labyrinth structure 101c. The base 101 is formed of, for example, titanium (Ti).

The flow path 101d maintains the bottom surface of the electrostatic chuck module 100 at the same temperature as the coolant. The concave part 101a and the convex part 101b include components such as the insulator 102 within the base 101. The convex part 101b is disposed along the outer circumference of the concave part 101a.

The convex part 101b is bonded to the crack plate 103. The convex part 101b allows the transfer and dissipation of heat from the crack plate 103. The convex part 101b is bonded to the crack plate 103 by one of the following methods: brazing, diffusion bonding, ultrasonic welding, electric welding, or welding.

The labyrinth structure 101c is disposed below the convex part 101b of the base 101. The labyrinth structure 101c regulates the amount of heat diffusing from the crack plate 103 to the base 101. An aluminum oxide (Al₂O₃) thermal spray film is formed on the outer surface of the base 101.

The insulator 102 is disposed in the concave part 101a of the base 101. The insulator 102 blocks the diffusion of heat. The thermal conductivity of the insulator 120 is 1 W/m·K or less in an operating temperature range. The insulator 102 is disposed between the crack plate 103 and the base 101 so that the heat from the resistance heating element 106 does not directly transfer to the base 101. If the temperature at the interface of the insulator 102 with the base 101 falls below 300° C., the insulator 102 is bonded to the base 101 with a silicone adhesive. If the temperature exceeds 300° C., the insulator 102 is bonded to the base 101 with an inorganic adhesive.

The resistance heating element 106 is disposed between the insulator 102 and an inorganic adhesive 105. The resistance heating element 106 is sheet-shaped. The resistance heating element 106 is disposed in a groove formed in the insulator 102. The resistance heating element 106 is disposed on or within the insulator 102. If the resistance heating element 106 is disposed within the insulator 102, the resistance heating element 106 is positioned near the crack plate 103, above the middle, in the vertical direction, of the insulator 102. The resistance heating element 106 generates heat by passing electricity therethrough. A plurality of resistance heating elements 106 may be provided, in which case, the plurality of resistance heating elements 106 are arranged in a concentric circular manner. The plurality of resistance heating elements 106 can be independently heated to a temperature of 300° C. or higher. In this manner, the plurality of resistance heating elements 106 heat the surface of the electrostatic chuck module 100 to a temperature between 300° C. and 600° C., while uniformly maintaining the temperature of the electrostatic chuck module 100. In addition, the inorganic adhesive 105 is interposed between the resistance heating element 106 and the crack plate 103, which is formed of a metal, to prevent a short circuit due to direct contact.

The crack plate 103 is disposed on the insulator 102 and the resistance heating element 106. The crack plate 103 uniformly distributes the heat generated by the resistance heating element 106. The crack plate 103 is formed of a metal with a thermal conductivity of 100 W/m·K or greater, and a material is chosen for the crack plate 103 that minimizes the difference in thermal expansion coefficient between the crack plate 103 and the ceramics plate 104. For example, the crack plate 103 is formed of molybdenum (Mo), which has a thermal expansion coefficient of 5.1×10⁻⁶/K and a thermal conductivity of 118 W/m. K at a temperature of 527° C.

As illustrated in FIG. 2, the crack plate 103 is bonded to the resistance heating element 106 using an inorganic adhesive 105. The crack plate 103 may be bonded to the insulator 102 using an inorganic adhesive 105 when the resistance heating element 106 is disposed within the insulator 102. An Al₂O₃ thermal spray film is formed on the outer surface of the crack plate 103. Therefore, the crack plate 103 is bonded to the resistance heating element 106 or insulator 102 either directly or indirectly using the inorganic adhesive 105. In addition, an insulating plate coated with the inorganic adhesive 105 on both sides thereof is interposed between the crack plate 103 and the resistance heating element 106. In an embodiment, as illustrated in FIG. 3, an Al₂O₃ thermal spray film is formed on the surface of the crack plate 103 that faces the insulator 102 to interpose the insulating material 108 between the crack plate 103 and the insulator 102, in which case the resistance heating element 106 is not directly in contact with the crack plate 103.

The ceramics plate 104 is disposed on the crack plate 103. The ceramics plate 104 incorporates an electrode 107 that adsorbs a target object such as a wafer substrate with static electricity. The ceramics plate 104 is formed of, for example, Al₂O₃, which has a thermal expansion coefficient of 5.4×10⁻⁶/K and a thermal conductivity of 11.4 W/m·K at a temperature of 500° C.

The electrostatic chuck module 100 can be manufactured by a following process. Mechanical machining is performed that forms a groove for a flow path in a Ti plate, which is then bonded with a metal brazing material that encapsulates the flow path. The Ti plate is mechanically machined into a required shape. Insulating porcelain parts are bonded to the ceramics plate 104 and to the crack plate 103. The ceramics plate 104 and the crack plate 103 are bonded together by a brazing or a similar method.

The insulator 102 is mechanically machined to form shapes, such as a groove for the resistance heating element 106. Power supply terminals are mounted to the ends of the resistance heating element 106 by a welding or a similar method. The resistance heating element 106 is arranged along the groove in the insulator 102. The resistance heating element 106 is bonded with the crack plate 103 and the interposed insulating material 108 using the inorganic adhesive 105. A silicone adhesive or the inorganic adhesive 105 is applied to the back surface of the insulator 102, bonding the insulator 102 to the base 101. At this stage, screws fitted with one or more disc springs that fix the base 101 and the crack plate 103 can be tightened.

The crack plate 103 is bonded to the base 101 by a method such as brazing or welding. If there are any bulges on the bonded surfaces, the bonded surfaces are smoothed by machining. Subsequently, Al₂O₃ thermal spraying is performed on some surfaces of the crack plate 103 and the base 101. A first defect inspection of the electrostatic chuck module 100 is conducted from the side of the ceramics plate 104 using an ultrasonic inspection device. The electrostatic chuck module 100 is determined to pass the first defect inspection if the bonded area of the crack plate 103 and the base 101 covers more than 99% with no significant defects.

A heating test is conducted by passing a current through the heating mechanism of the electrostatic chuck module 100 that ensures that the target object reaches a temperature of 300° C. or higher. The defect inspection of the electrostatic chuck module 100 is conducted again with an ultrasonic inspection device that ensures that there are no changes from after the bonding of the base 101 and the crack plate 103. The acceptance criteria for the second defect inspection are the same as before the heating test.

With the above configuration, the electrostatic chuck module 100 can heat to a temperature of 300° C. or higher a target object fixed by adsorption, and enables rapid heating and cooling while suppressing damage to the target object or the ceramics plate 104.

In a configuration where the base 101 is not bonded to the crack plate 103, the escape of heat from the crack plate 103 to the base 101 is minimal, in which case the surface temperature of the electrostatic chuck module 100 might not decrease. However, when the base 101 is bonded to the crack plate 103, heat flow from the crack plate 103 to the base 101 increases. This allows for rapid cooling of the surface of the electrostatic chuck module 100 when the resistance heating element 106 is turned off.

### Material Selection for an Electrostatic Chuck Module

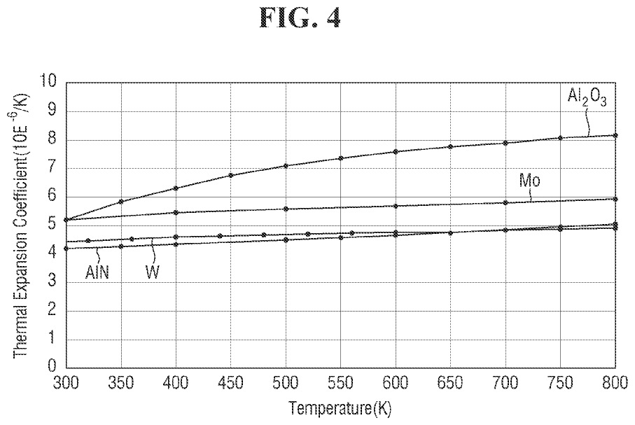

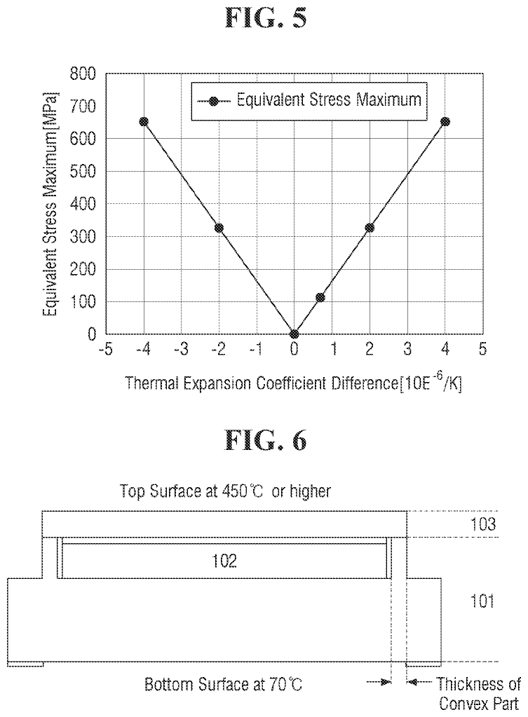

FIG. 4 is a graph of a relationship between the thermal expansion coefficient of the materials for an electrostatic chuck module according to an embodiment and the temperature of the electrostatic chuck module according to an embodiment. FIG. 5 is a graph of the relationship between the difference in thermal expansion coefficient between the materials for an electrostatic chuck module according to an embodiment and the stress occurring between these materials. The selection of materials for the electrostatic chuck module according to an embodiment will hereinafter be described with reference to FIGS. 4 and 5.

Referring to FIG. 4, in an embodiment, the thermal expansion coefficient of tungsten approaches the thermal expansion coefficient of aluminum nitride (AlN) in the range of operating temperatures for the electrostatic chuck module 100, i.e., from 300 K to 800 K. Tungsten, which is a metal with a thermal conductivity of over 100 W/m. K, can be used for the crack plate 103, and AlN can be used for the ceramics plate 104.

An increase in the difference between the thermal expansion coefficients of the ceramics plate 104 and the crack plate 103 can lead to breakage of the ceramics plate 104. Thus, a permissible range for the difference in thermal expansion coefficient between the ceramics plate 104 and the crack plate 103 is assessed. Materials such as aluminum oxide, which is typically used for the ceramics plate 104, tend to break under stresses exceeding 300 MPa. As shown in FIG. 5, a stress over 300 MPa is generated when the difference in thermal expansion coefficient between the ceramics plate 104 and the crack plate 103 surpasses ±2×10⁻⁶/K. Consequently, materials chosen for the crack plate 103 and the ceramics plate 104 should reduce the difference between the thermal expansion coefficients of the crack plate 103 and the ceramics plate 104 to within ±2×10⁻⁶/K.

### Thickness of Convex Part of an Electrostatic Chuck Module

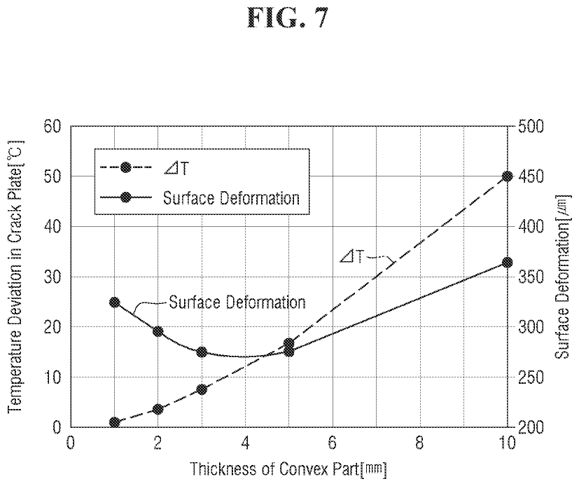

FIG. 6 illustrates a configuration of the thickness of the convex part of an electrostatic chuck module according to an embodiment. FIG. 7 is a graph of simulation results of the relationship between the thickness of the convex part of an electrostatic chuck module according to an embodiment, the temperature deviation in the crack plate of an electrostatic chuck module according to an embodiment, and surface deformation. The thickness of the convex part of an electrostatic chuck module according to an embodiment will hereinafter be described with reference to FIGS. 6 and 7.

Referring to FIG. 6, in an embodiment, the thickness of the convex part 101 corresponds to the width in a horizontal direction of the convex part 101 in a cross-sectional view of the electrostatic chuck module 100. Assuming that the thickness of the convex part 101b is the width of a joint part between the convex part 101b and the crack plate 103, a simulation was conducted with the top and bottom surfaces of the electrostatic chuck module 100 at temperatures of 450° C. or higher and 70° C., respectively, to examine the temperature deviation in the crack plate 103 and surface deformation.

The results of the simulation are as shown in FIG. 7. Referring to FIG. 7, in an embodiment, the higher the temperature, the greater the temperature variation in the crack plate 103. In an embodiment, a smaller temperature deviation is used. For example, if a permissible temperature deviation is set to be ±2% of 450° C., the difference between the maximum and minimum temperatures is 18° C. or less. Thus, the thickness of the convex part 101b may be 5 mm or less.

Moreover, a surface deformation should be small. In consideration of the deformation of wafer substrates and the forces therefor, an electrostatic adsorption force may be 4.0 N per 100 μm of wafer substrate deformation. Since the electrostatic adsorption force of the ceramics plate 104 is approximately 14 N at 2.5 kV, the ceramics plate 104 can accommodate a wafer substrate deformation of about 300 μm. Therefore, to achieve the amount of wafer deformation that can be absorbed, as indicated in FIG. 7, the thickness of the convex part 101b may be between 2 mm and 6 mm.

In conclusion, based on the simulation results for the temperature deviation in the crack plate 103 and surface deformation, the thickness of the convex part may be between 2 mm and 5 mm.

### Fixation by Fastening Members of an Electrostatic Chuck Module

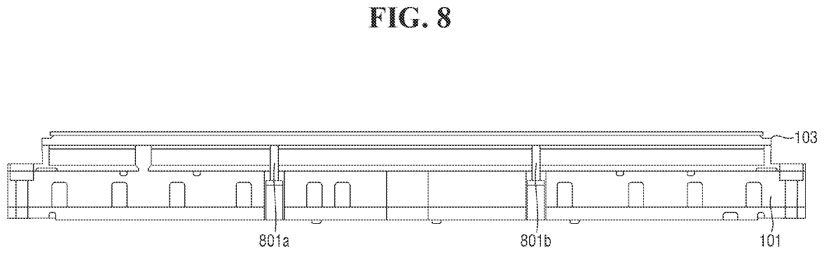

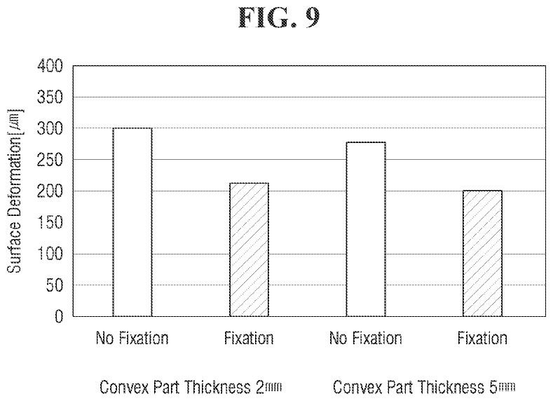

FIG. 8 illustrates an electrostatic chuck module according to an embodiment, fixed with fastening members. FIG. 9 is a graph of surface deformations of an electrostatic chuck module according to an embodiment when not fixed with fastening members and when fixed with fastening members. The fixation of an electrostatic chuck module according to an embodiment by fastening members will hereinafter be described with reference to FIGS. 8 and 9.

Referring to FIG. 8, in an embodiment, the base 101 and the crack plate 103 can be fixed with, for example, fastening members 801a and 801b. Consequently, surface deformation of the ceramics plate 104 can be further suppressed. FIG. 8 illustrates fixation on the side of the base 101 with the fastening members 801a and 801b, but fixation on the side of the crack plate 103 with the fastening members 801a and 801b is also possible. The fastening members 801a and 801b may be, for example, screws or rivets. The fixation with the fastening members 801a and 801b can be further strengthened using dish springs or members with spring force, such as springs.

FIG. 9 shows that regardless of the thickness of the convex part 101b of the base 101, the fixation of the base 101 and the crack plate 103 with fastening members reduces surface deformation compared to when there is no fixation between the base 101 and the crack plate 103. Therefore, upward bulging deformations caused by the thermal expansion of the crack plate 103 at high temperature can be suppressed and the amount of deformation of a wafer substrate during electrostatic adsorption can be reduced. In addition, the load on the joint part between the base 101 and the crack plate 103 due to deformation caused by the thermal expansion of the materials, ranging from the material of the insulator 102 to the material of the ceramics plate 104, can be reduced, and the bonding reliability at high temperature can be increased.

According to embodiments of the disclosure, an electrostatic chuck module that operates at temperatures above the heat resistance temperature of a resin can be provided. The operating temperature of the electrostatic chuck module can be maintained at 300° C. or higher, and a high uniform heating control can be achieved for a target object mounted on the surface of the ceramics plate. The stress applied to the ceramics plate due to thermal expansion can be reduced to a predetermined value or less, and the breakage of the ceramics plate can be prevented. The temperature deviation in the crack plate can be suppressed, the surface deformation of the crack plate can be prevented. The bonding between the crack plate and the insulator can be maintained at high temperatures above the heat resistance temperature of a resin. The crack plate, which is formed of a metal, can be prevented from being in direct contact with, and short-circuited by, the resistance heating element, which generates heat with electricity. The amount of heat transferred from the crack plate to the base can be reduced, the temperature deviation on the surface of the crack plate can be reduced, and consequently, and a uniform heating of a target object that is electrostatically adsorbed is enabled. Surface deformation of the electrostatic chuck module can be alleviated.

However, embodiments of the present disclosure are not limited to the above-described embodiments and can be appropriately modified without deviating from the scope of the inventive concept.

What is claimed is:

1. An electrostatic chuck module, comprising:
a base that includes a flow path for a coolant disposed below the base, a concave part disposed on the base, and a convex part, which is disposed along an outer circumference of the base;
an insulator disposed in the concave part of the base;
a resistance heating element disposed on or within the insulator;
a crack plate disposed on the insulator and the resistance heating element; and
a ceramics plate disposed on the crack plate and that includes an electrode that adsorbs a target object with static electricity,
wherein the convex part of the base is bonded to the crack plate.

2. The electrostatic chuck module of claim 1, wherein
the resistance heating element includes a plurality of resistance heating elements,
the plurality of resistance heating elements are arranged in a concentric circular manner, and
the plurality of resistance heating elements are independently heated to a temperature of 300° C. or higher.

3. The electrostatic chuck module of claim 1, wherein a difference between thermal expansion coefficients of the ceramics plate and the crack plate is +2×10⁻⁶/K or less at operating temperatures.

4. The electrostatic chuck module of claim 1, wherein a thickness of the convex part of the base is between 2 mm and 5 mm.

5. The electrostatic chuck module of claim 1, further comprising an inorganic adhesive that directly or indirectly bonds the crack plate to the insulator.

6. The electrostatic chuck module of claim 5, further comprising an insulating material interposed between the crack plate and the insulator, wherein the resistance heating element is not directly in contact with the crack plate.

7. The electrostatic chuck module of claim 1, further comprising a labyrinth structure disposed below the convex part of the base.

8. The electrostatic chuck module of claim 1, further comprising fastening members that fix the crack plate to the base.

9. The electrostatic chuck module of claim 8, further comprising dish springs or members with spring force that fix the crack plate to the base.

10. An electrostatic chuck module, comprising:
a base that includes a flow path for a coolant disposed below the base, a concave part disposed on the base, and a convex part disposed along an outer circumference of the base;
an insulator disposed in the concave part of the base;
a resistance heating element disposed on or within the insulator; and
a crack plate disposed on the resistance heating element and in contact with the convex part,
wherein a width of the convex part is between 2 mm and 5 mm.

11. The electrostatic chuck module of claim 10, further comprising:
a ceramics plate disposed on the crack plate and that includes an electrode that adsorbing a target object with static electricity.

12. The electrostatic chuck module of claim 11, wherein a difference between thermal expansion coefficients of the ceramics plate and the crack plate is ±2×10⁻⁶/K or less at operating temperatures.

13. The electrostatic chuck module of claim 10, wherein
the resistance heating element includes a plurality of resistance heating elements,
the plurality of resistance heating elements are arranged in a concentric circular manner, and
the plurality of resistance heating elements are independently heated to a temperature of 300° C. or higher.

14. The electrostatic chuck module of claim 10, further comprising:
an inorganic adhesive disposed between the crack plate and the resistance heating element.

15. The electrostatic chuck module of claim 10, further comprising:
an insulating material disposed between the crack plate and the inorganic adhesive.

16. The electrostatic chuck module of claim 10, further comprising a labyrinth structure disposed below the convex part of the base.

17. The electrostatic chuck module of claim 10, further comprising fastening members that fix the crack plate to the base.

18. The electrostatic chuck module of claim 17, further comprising dish springs or members with spring force that fix the crack plate to the base.

19. An electrostatic chuck module, comprising:
a base that includes a flow path for a coolant disposed below the base, a concave part disposed on the base, and a convex part disposed along an outer circumference of the base;
an insulator disposed in the concave part of the base;
a resistance heating element disposed on or within the insulator;
an inorganic adhesive disposed on the resistance heating element; and
a crack plate disposed on the inorganic adhesive, wherein the inorganic adhesive fixes the crack plate to the insulator and the resistance heating element such that the crack plate is in contact with the convex part and spaced apart from the concave part.

20. The electrostatic chuck module of claim 19, further comprising:
an insulating material disposed between the crack plate, the insulator, and the resistance heating element.
